(19) United States
(12) Patent Application Publication
(10) Pub. No.: US 2025/0022996 A1
(43) Pub. Date: Jan. 16, 2025

(54) LIGHT-EMITTING MODULE

(71) Applicant: NICHIA CORPORATION, Anan-shi (JP)

(72) Inventors: Tetsuya MIWA, Anan-shi (JP); So SAKAMAKI, Anan-shi (JP)

(73) Assignee: NICHIA CORPORATION, Anan-shi (JP)

(21) Appl. No.: 18/898,677

(22) Filed: Sep. 27, 2024

Related U.S. Application Data
(63) Continuation of application No. PCT/JP2023/011534, filed on Mar. 23, 2023.

(30) Foreign Application Priority Data
Mar. 30, 2022 (JP) 2022-056702

(51) Int. Cl. H01L 33/60; H01L 25/075; H01L 33/62

(52) U.S. Cl. CPC H01L 33/60; H01L 25/0753; H01L 33/62

(57) ABSTRACT

A light-emitting module including a substrate including a support member having a first surface and a wiring layer provided on the first surface, and a plurality of light-emitting elements provided on the first surface and electrically connected to the wiring layer. A plurality of light adjustment members is provided on a side of upper surfaces of the light-emitting elements, and spaced apart from the light-emitting elements, respectively. At least one light-shielding member is provided on the first surface, provided surrounding a first light-emitting element among the light-emitting elements and a first light adjustment member among the light adjustment members in plan view, and provided between the first light-emitting element and a second light-emitting element among the light-emitting elements in cross-sectional view. A light-transmissive member covers the first surface, the wiring layer, the light-emitting elements, the light adjustment members, and the at least one light-shielding member.

### CROSS-REFERENCE TO RELATED APPLICATIONS

The present application is a continuation application of PCT Application No. PCT/JP2023/011534, filed Mar. 23, 2023, which claims priority to Japanese Patent Application No. 2022-056702, filed Mar. 30, 2022. The contents of these applications are incorporated herein by reference in their entireties.

### BACKGROUND

### 1. Technical Field

Embodiments relate to a light-emitting module.

### 2. Description of Related Art

Light-emitting modules including a large number of light-emitting elements arranged in a planar shape are widely used as backlights of liquid crystal displays and various planar light sources of displays and the like.

In such light-emitting modules, the luminance immediately above the light-emitting elements may locally increase, causing luminance unevenness when the light-emitting elements are arranged in a planar shape.

As a method for improving the non-uniformity of the luminance above the light-emitting elements, which causes the luminance unevenness, for example, a technique described in Patent Application Publication No. 2005-347467 is known as an example of the light-emitting element alone.

### SUMMARY

Embodiments herein provide light-emitting modules with less luminance unevenness.

A light-emitting module according to an embodiment includes a substrate including a support member having a first surface and a wiring layer provided on the first surface. A plurality of light-emitting elements is provided on the first surface and electrically connected to the wiring layer. A plurality of light adjustment members is provided, on a side of upper surfaces of the plurality of light-emitting elements, spaced apart from the plurality of light-emitting elements, respectively. At least one light-shielding member is provided on the first surface, provided surrounding a first light-emitting element among the plurality of light-emitting elements and a first light adjustment member among the plurality of light adjustment members in plan view, and provided between the first light-emitting element and a second light-emitting element among the plurality of light-emitting elements in cross-sectional view. A light-transmissive member covers the first surface, the wiring layer, the plurality of light-emitting elements, the plurality of light adjustment members, and the light-shielding member.

An embodiment thereof can provide a light-emitting module with less luminance unevenness.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings. FIG. 1 is a schematic top view illustrating a light-emitting module according to a first embodiment.

FIG. 2 is an enlarged view of a part II in FIG. 1.

FIG. 3 is a cross-sectional view taken along line III-III in FIG. 1, and is a schematic cross-sectional view illustrating the light-emitting module according to the first embodiment.

FIG. 4 is a schematic cross-sectional view for explaining an operation of the light-emitting module according to the first embodiment.

FIG. 5A is a schematic graphical representation for explaining the operation of the light-emitting module according to the first embodiment.

FIG. 5B is a schematic graphical representation for explaining the operation of the light-emitting module according to the first embodiment.

FIG. 6A is a schematic cross-sectional view illustrating the light-emitting module according to the first embodiment.

FIG. 6B is a schematic cross-sectional view illustrating the light-emitting module according to the first embodiment.

FIG. 6C is a schematic cross-sectional view illustrating the light-emitting module according to the first embodiment.

FIG. 7 is a schematic cross-sectional view illustrating the light-emitting module according to the first embodiment.

FIG. 8 is a schematic cross-sectional view illustrating the light-emitting module according to the first embodiment.

FIG. 9 is a schematic top view illustrating a first modified example of the light-emitting module according to the first embodiment.

FIG. 10A is a schematic top view illustrating a second modified example of the light-emitting module according to the first embodiment.

FIG. 10B is a schematic top view illustrating a third modified example of the light-emitting module according to the first embodiment.

FIG. 11A is a schematic top view illustrating a fourth modified example of the light-emitting module according to the first embodiment.

FIG. 11B is a schematic top view illustrating a fifth modified example of the light-emitting module according to the first embodiment.

FIG. 12 is a schematic top view illustrating a sixth modified example of the light-emitting module according to the first embodiment.

FIG. 13 is a schematic top view illustrating a seventh modified example of the light-emitting module according to the first embodiment.

FIG. 14 is a schematic cross-sectional view illustrating a light-emitting module according to a second embodiment.

FIG. 15 is a schematic cross-sectional view illustrating a light-emitting module according to a modified example of the second embodiment.

FIG. 16 is a schematic cross-sectional view illustrating a light-emitting module according to a third embodiment.

FIG. 17 is a schematic cross-sectional view illustrating a light-emitting module according to a fourth embodiment.

### DETAILED DESCRIPTION OF EMBODIMENT

### Description of Embodiments

Embodiments of the present invention are described below with reference to the drawings.

Note that the drawings are schematic or conceptual, and the relationships between thicknesses and widths of portions, the proportions of sizes between portions, and the like are not necessarily the same as the actual values thereof. Furthermore, the dimensions and the proportions may be illustrated differently between the drawings, even in a case in which the same portion is illustrated.

Note that, in the specification and the drawings, elements similar to those described in relation to a drawing thereinabove are denoted using like reference characters, and a detailed description is omitted as appropriate.

### First Embodiment

FIG. 1 is a schematic top view illustrating a light-emitting module according to

a first embodiment.

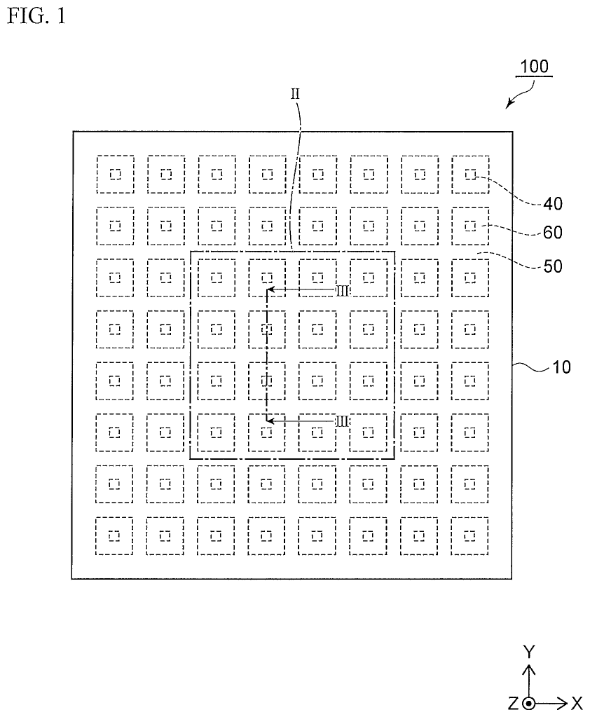

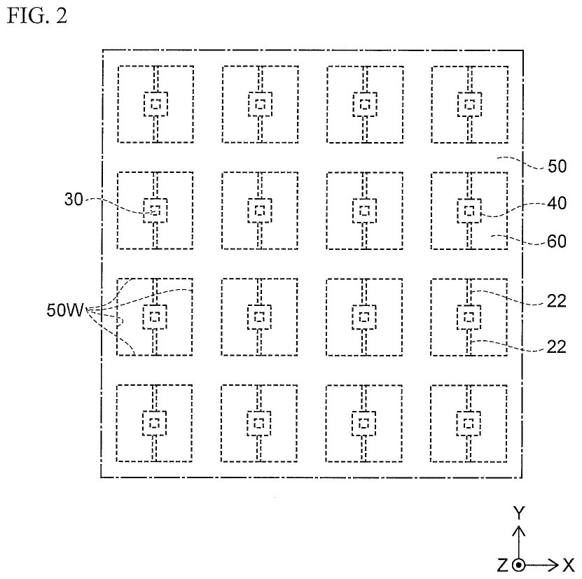

FIG. 2 is an enlarged view of a part II in FIG. 1.

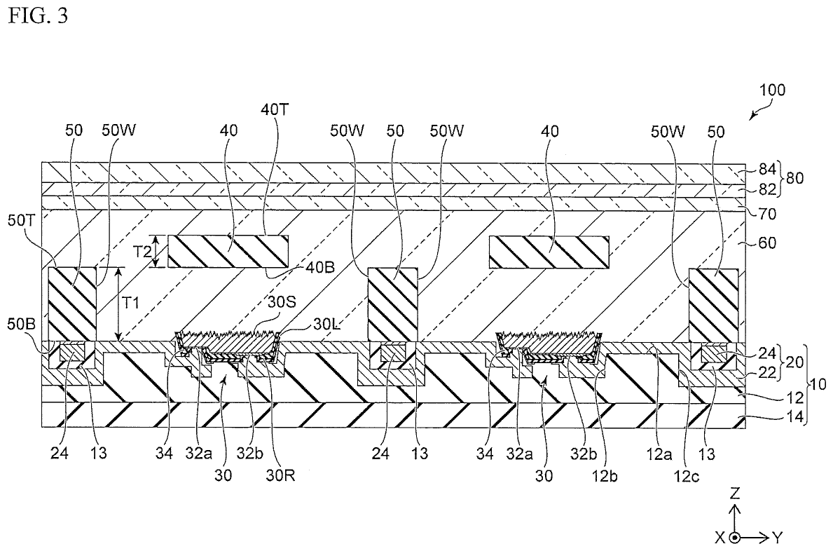

FIG. 3 is a cross-sectional view taken along line III-III in FIG. 1, and is a schematic cross-sectional view illustrating the light-emitting module according to the first embodiment.

As illustrated in FIGS. 1 to 3, a light-emitting module 100 according to the present embodiment includes a substrate 10, a plurality of light-emitting elements 30, a plurality of light adjustment members 40, a light-shielding member 50, and a first light-transmissive member 60. The substrate 10 includes a support member 12, a first wiring layer 22, and a second wiring layer 24. As in this example, the substrate 10 can include a reinforcing substrate 14. The support member 12 has a first surface 12a. The first wiring layer 22 is arranged on the first surface 12a.

In the description of all embodiments and modified examples thereof, a three-dimensional XYZ coordinate system may be used. The XY plane is a plane substantially parallel to the first surface 12a. It is assumed that the direction of an X axis is a direction along the row direction of the plurality of light-emitting elements 30 arranged in a matrix. It is assumed that the direction of a Y axis is a direction along the column direction of the plurality of light-emitting elements 30 arranged in a matrix. The Y axis is orthogonal to the X axis. A Z axis is orthogonal to the XY plane. It is assumed that an orientation from a surface located on the opposite side of the support member 12 from the first surface 12a toward the first surface 12a is a positive direction.

The positive direction of the Z axis is sometimes referred to as “up”, “upper”, or “upward” and the negative direction of the Z axis is sometimes referred to as “down”, “lower”, or “downward”. However, the direction along the Z axis is not necessarily the direction in which gravity is applied. These are intended to facilitate understanding of the description, and are not limited to actual “up”, “upward”, and the like. The length in the Z-axis direction may be referred to as a thickness.

As illustrated in FIGS. 1 and 2, in the light-emitting module 100, the plurality of light-emitting elements 30 are arranged in a matrix of eight rows x eight columns on the substrate 10 that is substantially square. The number of light-emitting elements 30 to be arranged is not limited thereto, and for example, the number of light-emitting elements 30 can be set as necessary according to the application thereof. The arrangement of the plurality of light-emitting elements 30 is not limited to the grid-like matrix arrangement as illustrated in FIG. 1, and can be any appropriate arrangement such as a staggered arrangement or a hexagonal close-packed arrangement.

In the arrangement of the plurality of light-emitting elements 30 in the example of FIG. 1, an interval between adjacent light-emitting elements 30 is the same for all the light-emitting elements 30; however, no such limitation is intended and the light-emitting elements 30 can be arranged at different intervals depending on the locations of the light-emitting elements 30. For example, in the corner of the light-emitting module 100, the number of adjacent light-emitting elements is reduced, and interference due to light between the light-emitting elements is reduced, and thus the luminance is lower than that in the center portion of the light-emitting module 100. Therefore, the interval between the light-emitting elements 30 can be narrower in the corner of the light-emitting module 100 than the interval between the light-emitting elements 30 in the center portion of the light-emitting module 100, to increase the luminance. The shape of the substrate 10 is not limited to a square, and can be a rectangle or any polygon such as a trapezoid or a rhombus depending on the number of the light-emitting elements 30 to be arranged and the aspect of arrangement.

In the light-emitting module 100, the light-emitting element 30 and the light adjustment member 40 are arranged between opposing inner wall surfaces 50W. In this example, the light-emitting element 30 and the light adjustment member 40 are surrounded by four inner wall surfaces 50W arranged in a square shape. The four inner wall surfaces 50W are not separated and are continuously arranged. The first light-transmissive member 60 is arranged between the inner wall surface 50W and the light adjustment member 40. The first light-transmissive member 60 is also arranged between the inner wall surface 50W and the light-emitting elements 30. In this example, the light-emitting element 30 and the light adjustment member 40 also have substantially square outer peripheries, respectively.

In the light-emitting module 100, the first light-transmissive member 60 is arranged on the light-shielding member 50. The first light-transmissive member 60 covers a region surrounded by the inner wall surface 50W in XY plan view, and the light-emitting element 30 and the light adjustment member 40 are also covered with the first light-transmissive member 60. In FIG. 2, in order to avoid complexity of illustration, the first wiring layer 22 in a region surrounded by an inner periphery of the inner wall surface 50W is indicated by a broken line. As described with reference to FIG. 3, actually, the first wiring layer 22 is also arranged below the light-shielding member 50, and the second wiring layer 24 is also arranged below the light-shielding member 50.

In the light-emitting module 100 according to the present embodiment, light emitted from one light-emitting element 30 is emitted as light obtained by combining light emitted from a region between the light adjustment member 40 and the inner wall surface 50W with light emitted through the light adjustment member 40. Therefore, in the light-emitting module 100 of the present embodiment, the relative relationship between the light adjustment member 40 and the inner wall surface 50W in XY plan view is determined such that light is also emitted from the region between the light adjustment member 40 and the inner wall surface 50W.

More specifically, in XY plan view, the area of a region surrounded by the inner peripheries of the four inner wall surfaces 50W is larger than the area of a region surrounded by an outer periphery of the light adjustment member 40. Therefore, a part of light emitted from the light-emitting element 30 is emitted through the light adjustment member 40, and the other part thereof is emitted from the region between the light adjustment member 40 and the inner wall surface 50W. The light emitted from the light-emitting element 30 is emitted as light obtained by combining the light emitted from the region between the light adjustment member 40 and the inner wall surface 50W with the light emitted from the light adjustment member 40. The light emitted from the light-emitting element 30 is emitted with a distribution of luminance of the combined light.

In the light-emitting module 100 of the present embodiment, the mutual dimensions of the light adjustment member 40 and the light-shielding member 50 are set such that the light-emitting module 100 serves as a planar light source with less luminance unevenness with respect to light emitted from the light-emitting element 30 and combined. As described in detail below, the luminance of the light emitted from the light adjustment member 40 depends on a plurality of parameters such as the light transmittance of the light adjustment member 40 itself, a distance between the light-emitting element 30 and the light adjustment member 40, and the magnitude of the light reflectance of the light adjustment member 40. The luminance of light emitted from the region between the light adjustment member 40 and the inner wall surface 50W also depends on a plurality of parameters such as the reflectances of the light-shielding member 50 and the support member 12. By appropriately setting these parameters, the light-emitting module 100 with reduced luminance unevenness is implemented.

In the light-emitting module 100, the plurality of light-emitting elements 30 are electrically connected to each other by the first wiring layer 22. As described below with reference to FIG. 3, the second wiring layer 24 is arranged below the light-shielding member 50.

As illustrated in FIGS. 2 and 3, a wiring layer 20 includes the first wiring layer 22 and the second wiring layer 24. As in this example, when the first wiring layer 22 and the second wiring layer 24 are wired so as to intersect each other, the first wiring layer 22 and the second wiring layer 24 are insulated from each other at the intersection. In this example, the second wiring layer 24 is insulated from the first wiring layer 22 via an insulating layer 13.

As illustrated in FIGS. 2 and 3, wiring lines constituting the first wiring layer 22 are arranged along the column direction of the plurality of light-emitting elements 30 arranged in a matrix, and wiring lines constituting the second wiring layer 24 are arranged along the row direction of the plurality of light-emitting elements 30 arranged in a matrix. The arrangement of the wiring lines constituting each of the first wiring layer 22 and the second wiring layer 24 is determined by the circuit configuration of the light-emitting module 100, and the wiring lines can be arranged along any direction. Also in this example, the first wiring layer 22 includes wiring lines arranged along the row direction, and the second wiring layer 24 includes wiring lines arranged along the column direction. For example, when the light-emitting module 100 is matrix-driven, a circuit configuration in which the first wiring layer 22 and the second wiring layer 24 are arranged in a matrix is employed. When the light-emitting module 100 is matrix-driven, the light-emitting module 100 can be driven for each light-emitting element 30, or the light-emitting module 100 can be driven in units of segments each using the plurality of light-emitting elements 30 as one light source. By employing the matrix driving in the light-emitting module 100, a local dimming operation can be implemented.

As illustrated in FIG. 3, a plurality of recessed portions 12b are arranged on the first surface 12a. The plurality of recessed portions 12b are arranged in a matrix at positions where the plurality of light-emitting elements 30 are arranged, respectively. A plurality of recessed portions 12c are arranged on the first surface 12a. The plurality of recessed portions 12c are arranged along the X-axis direction. The plurality of recessed portions 12c are arranged along the Y-axis direction, and are arranged in a lattice shape surrounding the recessed portion 12b.

The first wiring layer 22 is arranged on the first surface 12a. A plurality of the wiring lines constituting the first wiring layer 22 are arranged along the Y-axis. These wiring lines are arranged on the plurality of recessed portions 12b and are also arranged on the plurality of recessed portions 12c.

The insulating layer 13 is arranged on the plurality of recessed portions 12c and the wiring lines arranged in the recessed portions 12c. The second wiring layer 24 is arranged along the X-axis direction on the insulating layer 13.

The support member 12 is preferably formed of a light-reflective resin. The light-reflective resin is, for example, a thermosetting resin having excellent heat resistance and light resistance. For example, a silicone resin, an epoxy resin, or the like can be suitably used for the light-reflective resin. For example, a member having light reflectivity can be obtained by mixing a light-reflective filler into a silicone resin. The light-reflective filler can be, for example, TiO₂. The thickness of the support member 12 can be, for example, about in a range from 15 μm to 300 μm.

The substrate 10 can include a reinforcing substrate 14. The reinforcing substrate 14 is arranged on a surface side located on the opposite side of the support member 12 from the first surface 12a. The reinforcing substrate 14 is used to reinforce the strength of the support member 12. In order to reduce the thickness of the light-emitting module 100, the support member 12 is desirably sufficiently thin. When the support member 12 is thin, the support member 12 may be prone to warping or wrinkling, and maintaining dimensional accuracy may be difficult. Therefore, sufficiently maintaining the strength of the substrate 10 is difficult. In this regard, additionally arranging the reinforcing substrate 14 suppresses such warping and wrinkling and reinforces insufficient strength of the support member 12. For example, a substrate using a glass cloth impregnated with polyimide can be used for the reinforcing substrate 14, so that both sufficient thinness and strength can be achieved. The thickness of the reinforcing substrate 14 can be, for example, in a range from about 25 μm to 200 μm.

The light-emitting element 30 has a light extraction surface 30S and an electrode formation surface 30R. The electrode formation surface 30R is located on the opposite side of the light extraction surface 30S. The light-emitting element 30 has a lateral surface 30L. The lateral surface 30L is located between the light extraction surface 30S and the electrode formation surface 30R. The light extraction surface 30S is an upper surface of the light-emitting element 30, and the electrode formation surface 30R is a lower surface of the light-emitting element 30. For example, a light-reflecting film 34 is arranged on the lateral surface 30L. By arranging the light-reflecting film 34 on the lateral surface 30L, the efficiency of light extraction from the light extraction surface 30S can be increased.

In this example, the light-emitting element 30 has a quadrangular shape in XY plan view. The shape of the light-emitting element 30 in XY plan view is not limited to a quadrangle, and can be a polygon having three or more corners, a circle, or an ellipse. In the case of a polygon, the corners can be chamfered or rounded. In this example, the light-emitting element 30 is a truncated pyramid whose diameter increases from the electrode formation surface 30R toward the light extraction surface 30S. The shape of the light-emitting element 30 is not limited to the above and can be a truncated pyramid, a truncated cone, or a truncated elliptical cone whose diameter decreases from the electrode formation surface 30R toward the light extraction surface 30S. The light-emitting element 30 can have a columnar body having the same diameter from the electrode formation surface 30R to the light extraction surface 30S.

In the light-emitting element 30, light is emitted mainly from the light extraction surface 30S. In this example, the light extraction surface 30S is roughened, and the light emitted from the light extraction surface 30S is diffused over a wide range. The light extraction surface 30S is not limited to this and can be a flat surface substantially flattened. A part of light is also emitted from the lateral surface 30L and the electrode formation surface 30R.

A pair of electrodes 32a and 32b are arranged on the electrode formation surface 30R. The light-emitting element 30 includes a semiconductor structure, and the pair of electrodes 32a and 32b are connected to a p-type semiconductor layer and an n-type semiconductor layer that form the semiconductor structure. In the semiconductor structure, for example, a structure of a light-emitting diode is achieved by layering the p-type semiconductor layer, a light-emitting layer, and the n-type semiconductor layer.

The light-emitting layer can have a structure with a single active layer, such as a double heterostructure or a single quantum well structure (SQW), or can have a structure with a group of active layers, such as a multiple quantum well structure (MQW). The light-emitting layer can emit visible light or ultraviolet light. For example, visible light can include at least blue to red light. An example of the semiconductor structure including such a light-emitting layer can include In^{x}Al^{y}Ga^{1-x-y}N (0≤x, 0≤y, x+y≤1).

The light-emitting element 30 can include two or more light-emitting layers in the semiconductor structure. For example, the semiconductor structure can be a structure including two or more light-emitting layers between the n-type semiconductor layer and the p-type semiconductor layer, or can be a structure in which a structure of sequentially layering the n-type semiconductor layer, the light-emitting layer, and the p-type semiconductor layer is repeated twice or more. The two or more light-emitting layers can include, for example, light-emitting layers with different light emission colors or can include light-emitting layers with the same light emission color. The expression “the same light emission color” may include a variation in a range that can be considered as the same light emission color in use. For example, a dominant wavelength of each light emission color may vary by approximately several nanometers. A combination of the light emission colors can be selected as appropriate. For example, when the semiconductor structure includes two light-emitting layers, examples of the combination that can be used include blue light and blue light, green light and green light, red light and red light, ultraviolet light and ultraviolet light, blue light and green light, blue light and red light, and green light and red light.

The plurality of light-emitting elements 30 are arranged on the first surface 12a. Specifically, the plurality of light-emitting elements 30 are arranged in a matrix by being arranged in the plurality of recessed portions 12b, respectively. The light-emitting element 30 is arranged on the first wiring layer 22 arranged in the recessed portion 12b, and is electrically connected to the first wiring layer 22 via the electrodes 32a and 32b.

The plurality of light adjustment members 40 are arranged above the plurality of light-emitting elements 30, respectively. The plurality of light adjustment members 40 are spaced apart from the plurality of light-emitting elements 30, respectively. The first light-transmissive member 60 is arranged between the light adjustment member 40 and the light-emitting element 30. The light adjustment member 40 transmits a part of light from the light-emitting element 30 and reflects the other part thereof. When the light adjustment member 40 transmits a part of the light, the light adjustment member 40 preferably diffuses and emits the transmitted light. By diffusing the light transmitted through the inside of the light adjustment member 40, luminance unevenness over an entire upper surface 40T of the light adjustment member 40 can be reduced.

The light adjustment member 40 is a plate-shaped member having a substantially uniform thickness T2. The thickness T2 is a length in the Z-axis direction from a lower surface 40B of the light adjustment member 40 to the upper surface 40T of the light adjustment member 40. As described with reference to FIGS. 1 and 2, in XY plan view, the light adjustment member 40 has a substantially square shape in this example.

In XY plan view, the region surrounded by the outer periphery of the light adjustment member 40 overlaps at least a part of a region surrounded by an outer periphery of the light-emitting element 30. In this example, in XY plan view, the region surrounded by the outer periphery of the light adjustment member 40 completely overlaps the region surrounded by the outer periphery of the light-emitting element 30. When a diameter of the light adjustment member 40 is larger than a diameter of the light-emitting element 30, the outer periphery of the light adjustment member 40 is located on an outer side of the outer periphery of the light-emitting element 30 as in this example.

In this example, in XY plan view, the area of the region surrounded by the outer periphery of the light adjustment member 40 is larger than the area of the region surrounded by the outer periphery of the light-emitting element 30; however, no such limitation is intended. For example, the area of the region surrounded by the outer periphery of the light adjustment member 40 can be equal to the area of the region surrounded by the outer periphery of the light-emitting element 30, or can be smaller than the area of the region surrounded by the outer periphery of the light-emitting element 30.

For the light adjustment member 40, a material with a desired light transmittance is selected when the light adjustment member 40 has an appropriate thickness T2. The light adjustment member 40 is formed of, for example, a light-reflective resin. The light-reflective resin is preferably a thermosetting resin having excellent heat resistance and light resistance. When the light adjustment member 40 has the appropriate thickness T2 and a desired shape and area in XY plan view, a light-transmissive resin containing a light diffusion filler such as TiO₂ can be used as the light-reflective resin to sufficiently diffuse transmitted light. For example, a silicone resin, an epoxy resin, or the like can be suitably used for a base material of the light-reflective resin.

The light-shielding member 50 is arranged on the first surface 12a. More specifically, the light-shielding member 50 is arranged on the first surface 12a and the first wiring layer 22, and is also arranged on the insulating layer 13 arranged in the recessed portion 12c and the second wiring layer 24. The light-shielding member 50 has the inner wall surface 50W, and the inner wall surface 50W surrounds the light-emitting element 30 in XY plan view. Preferably, as illustrated in FIG. 3, the inner wall surface 50W is at an angle of approximately 90° to the first surface 12a. In other words, as illustrated in FIGS. 2 and 3, lengths (third lengths) in the X-axis direction and the Y-axis direction are substantially uniform. That is, a width W1 of the light-shielding member, which is a length in the X-axis direction, is substantially uniform along the Z-axis direction, which is the thickness direction of the light-shielding member. A width W2 of the light-shielding member, which is a length in the Y-axis direction, is substantially uniform along the Z-axis direction, which is the thickness direction of the light-shielding member. The width W1 and the width W2 can be the same as each other or different from each other. With this configuration, the light distribution of the light-emitting element 30 can be effectively controlled.

The light-shielding member 50 is arranged between two light-emitting elements 30, to control interference of light emitted by the two light-emitting elements 30. Light emitted by the light-emitting element 30 and emitted from the region between the light adjustment member 40 and the inner wall surface 50W is combined with light emitted by the light-emitting element 30 provided across the light-shielding member 50. A thickness T1 and a material of the light-shielding member 50 are set such that luminance unevenness of the light combined by the two light-emitting elements 30 is reduced.

The light-shielding member 50 is formed of a material having a light-blocking property against light emitted from the light-emitting element 30. For example, a material having light reflectivity, a material that absorbs light, or the like can be used for the light-shielding member 50. When the light-shielding member 50 has light reflectivity, light emitted from the light-emitting element 30 is reflected by the inner wall surface 50W and emitted to the outside, thereby improving substantial light emission efficiency of the light-emitting element 30. Preferably, the light-shielding member 50 is formed of a light-reflective resin. The light-reflective resin is preferably a thermosetting resin having excellent heat resistance and light resistance. For example, a silicone resin, an epoxy resin, or the like can be suitably used. For example, a member having light reflectivity can be obtained by mixing a light-reflective filler into a silicone resin. The light-reflective filler can be, for example, TiO₂.

The material forming the light-shielding member 50 is not limited to a material having light reflectivity and can be a material that absorbs light. A black resin can be used for a material that absorbs light. Even a resin colored in black can exhibit light-blocking performance. When the light-shielding member 50 is formed of a light-reflective resin, the light-shielding member 50 is preferably formed of the same material as the material of the light adjustment member 40 from the viewpoint of achieving uniform optical characteristics and reducing luminance unevenness.

The thickness T1 of the light-shielding member 50 is a length in the Z-axis direction from a lower surface 50B of the light-shielding member 50 to an upper surface 50T of the light-shielding member 50. The lower surface 50B is assumed to be in contact with the first surface 12a. The thickness T1 can be, for example, about in a range from 10 μm to 450 μm. When the light-shielding member 50 is formed of a light-reflective resin, the thickness T1 of the light-shielding member 50 is preferably thick in order to increase light extraction efficiency. Accordingly, from the viewpoint of implementing light with less luminance unevenness while increasing light extraction efficiency, the thickness T1 is preferably set equal to or greater than the thickness T2 of the light adjustment member 40.

From the viewpoint of suppressing luminance above the light-emitting elements 30 by the light adjustment member 40 and balancing the luminance of light emitted from the region between the light adjustment member 40 and the inner wall surface 50W, the lower surface 40B and the upper surface 50T can have an appropriate relative position in the Z-axis direction. In this example, the position of the lower surface 40B in the Z-axis direction is set so as to substantially coincide with the position of the upper surface 50T in the Z-axis direction.

Making the positions of the lower surface 40B and the upper surface 50T substantially coincident in the Z-axis direction has the advantage of simplifying a process of forming the light adjustment member 40 and the light-shielding member 50 in the manufacturing process of the light-emitting module 100. This is because the light adjustment member 40 and the light-shielding member 50 are formed in layers from the same material. From the viewpoint of such a manufacturing process, the upper surface 40T of the light adjustment member 40 and the upper surface 50T of the light-shielding member 50 can substantially coincide with each other.

The first light-transmissive member 60 covers the first surface 12a, the first wiring layer 22, the plurality of light-emitting elements 30, the plurality of light adjustment members 40, and the light-shielding member 50. The first light-transmissive member 60 covers the light-emitting elements 30 and the light adjustment member 40 in the region surrounded by the inner wall surface 50W of the light-shielding member 50.

The first light-transmissive member 60 is light-transmissive, and optically couples the light-emitting element 30 and a wavelength conversion member 70. The light-transmissive member 60 optically couples the light adjustment member 40 and the wavelength conversion member 70. A light-transmissive resin, for example, an epoxy resin, a silicone resin, or a resin in which these resins are mixed, glass, or the like can be used for the light-transmissive member 60.

The wavelength conversion member 70 is arranged on the first light-transmissive member 60. The wavelength conversion member 70 contains a wavelength conversion substance that converts light emitted by the light-emitting element 30 into light having a different wavelength. Examples of the wavelength conversion substance include phosphor materials. A phosphor sheet in which a phosphor material is dispersed in a sheet-like base material can be used for the wavelength conversion member 70. Examples of the phosphor material include a fluoride-based phosphor such as a YAG phosphor, a β sialon phosphor, or a KSF-based phosphor.

The wavelength conversion member 70 can contain one or a plurality of different types of wavelength conversion substances. In the case of containing a plurality of wavelength conversion substances, for example, the wavelength conversion member 70 can contain a β sialon phosphor that emits green light and a fluoride-based phosphor such as a KSF-based phosphor that emits red light. In the case in which a plurality of wavelength conversion substances are contained, the plurality of wavelength conversion substances can be contained in one layer, or a plurality of layers can be formed and each of the plurality of wavelength conversion substances can be contained in each layer of the plurality of layers. Use of the wavelength conversion member 70 containing the plurality of wavelength conversion substances can expand the color reproduction range of the light-emitting module 100.

As the wavelength conversion substance, a known phosphor can be used. As the phosphor, an yttrium-aluminum-garnet-based phosphor (for example, Y₃(Al,Ga)₅O₁₂: Ce), a lutetium-aluminum-garnet-based phosphor (for example, Lu₃(Al,Ga)₅O₁₂: Ce), a terbium-aluminum-garnet-based phosphor (for example, Tb₃(Al,Ga)₅O₁₂: Ce), a CCA-based phosphor (for example, Ca₁₀(PO₄)₆C₁₂: Eu), a SAE-based phosphor (for example, Sr₄Al₁₄O₂₅: Eu), a chlorosilicate-based phosphor (for example, Ca₈MgSi₄O₁₆C₁₂: Eu), an oxynitride-based phosphor, a nitride-based phosphor, a fluoride-based phosphor, a phosphor having a perovskite structure (for example, CsPb (F,Cl,Br,I)₃), a quantum dot phosphor (for example, CdSe, InP, AgInS₂, or AgInSe₂), or the like can be used. Typical examples of the oxynitride-based phosphors include β-sialon-based phosphors (for example, (Si,Al)₃(O,N)₄: Eu) and a-sialon-based phosphors (for example, Ca(Si,Al)₁₂(O,N)₁₆: Eu). Typical examples of the nitride-based phosphors include SLA-based phosphors (for example, SrLiAl₃N₄: Eu), CASN-based phosphors (for example, CaAlSiN₃: Eu), and SCASN-based phosphors (for example, (Sr,Ca) AlSiN₃: Eu). Typical examples of the fluoride-based phosphors include KSF-based phosphors (for example, K₂SiF₆: Mn), KSAF-based phosphors (for example, K₂Si_{0.99}Al_{0.01}F_{5.99}: Mn), and MGF-based phosphors (for example, 3.5MgO·_{0.5}MgF₂·GeO₂: Mn).

A resin or the like can be used for the base material in which the wavelength conversion substance is dispersed. For example, an epoxy resin, a silicone resin, or a resin in which these resins are mixed can be used for the resin material, or a light-transmissive material such as glass can be used. From the viewpoint of light resistance and ease of molding of the wavelength conversion member 70, a silicone resin is favorably selected as the base material.

In this example, an optical member 80 is arranged on the wavelength conversion member 70. The optical member 80 includes a light diffusion member 82 and a light scattering member 84. The light diffusion member 82 is arranged on the wavelength conversion member 70, and the light scattering member 84 is arranged on the light diffusion member 82.

The light diffusion member 82 diffuses light emitted by the light-emitting element 30 via the wavelength conversion member 70. The light scattering member 84 scatters the light emitted by the light-emitting element 30 via the wavelength conversion member 70. In the light-emitting module 100, such an optical member 80 is arranged on the wavelength conversion member 70, thereby avoiding local concentration of light and contributing to reduction of luminance unevenness.

The light diffusion member 82 is, for example, a light diffusion sheet. In the light diffusion sheet, irregularities for diffusing light are arranged on a surface of a resin sheet serving as a base material. A light diffusion agent can be further dispersed in the base material. Inorganic particles of TiO₂, SiO₂, Al₂O₃, a glass filler, or the like can be suitably used for the light diffusion agent. A material in which a white-based resin or a metal being a light-reflective member is processed in a shape of fine particles can also be used for the light diffusion agent. The base material is not limited to a resin sheet, and a thermosetting resin such as a silicone resin or an epoxy resin can be arranged by coating or the like and cured.

The light scattering member 84 is, for example, a prism sheet. The prism sheet includes a large number of grooves having prism angles and formed on the surface of a base material made of a resin, and scatters incident light. In the case of a prism sheet provided with grooves along one direction, for example, two prism sheets in which groove forming directions are orthogonal to each other can be used. Other than a prism sheet, a lens sheet in which a large number of lenses are formed on a base material, or the like can be used for the light scattering member 84. The optical member 80 is selectively available or not available depending on the configuration, application, and the like of the light-emitting module 100.

The operation of the light-emitting module 100 according to the present embodiment is described.

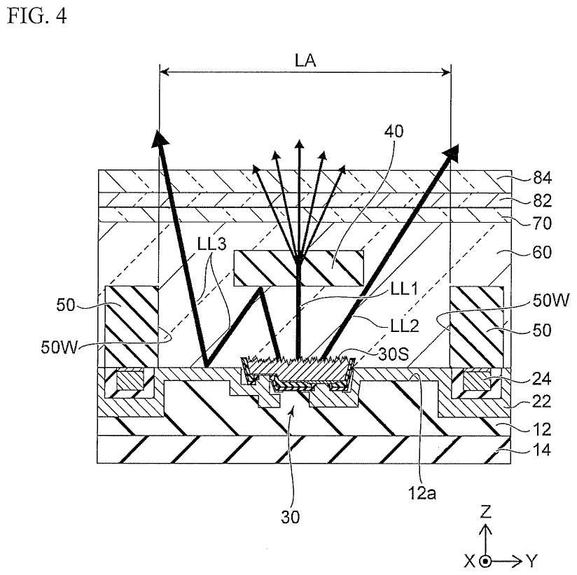

FIG. 4 is a schematic cross-sectional view for explaining the operation of the light-emitting module according to the first embodiment.

FIG. 4 illustrates a portion including one light-emitting element 30 in the cross-sectional view of the light-emitting module 100 illustrated in FIG. 3. LA denotes a distance between opposing inner wall surfaces 50W. LA is longer than a length of the light adjustment member 40 in the Y-axis direction. LA is longer than a length of the light-emitting element 30 in the Y-axis direction. Accordingly, a part of light emitted from the light-emitting element 30 is transmitted through the light adjustment member 40 and emitted, and another part of the light is emitted from the region between the light adjustment member 40 and the inner wall surface 50W. The components of the light-emitting module 100 are as described with reference to FIGS. 1 to 3, and the same components are denoted by the same reference characters and are not described in detail.

As illustrated in FIG. 4, the light-emitting element 30 mainly emits light upward from the light extraction surface 30S. The light is emitted from the light extraction surface 30S with a wide spread. FIG. 4 illustrates lights LL1, LL2, and LL3 in three types of directions. The thicknesses of arrows representing the lights LL1, LL2, and LL3 schematically represent luminance levels. The thicker the thickness of the arrow, the higher the luminance of the light indicated by the arrow. It is assumed that the three types of lights LL1, LL2, and LL3 have the same luminance on the light extraction surface 30S.

The light LL1, which is a part of the light emitted from the light-emitting element 30 and directed toward the light adjustment member 40, is incident on the light adjustment member 40. A part of the light LL1 incident on the light adjustment member 40 is transmitted through the light adjustment member 40. The rest of the light LL1 incident on the light adjustment member 40 is absorbed by the light adjustment member 40. The light LL1 incident on the light adjustment member 40 is diffused by the light-reflective filler dispersed in the light adjustment member 40, and is emitted from the light adjustment member 40 as light with luminance lower than the luminance of the incident light LL1.

Of the light emitted from the light-emitting element 30, the light LL2 directed to the region between the light adjustment member 40 and the light-shielding member 50 is emitted as is because no obstacle exists in an optical path.

The light LL3, which is another part of the light emitted from light-emitting element 30 and directed toward light adjustment member 40, is reflected by the light adjustment member 40 and travels downward. The light LL3 that is reflected and travels downward is reflected again by the first wiring layer 22 or the support member 12 and is emitted from the region between the light adjustment member 40 and the light-shielding member 50. The reflected light LL3 is emitted so as to be added to the directly emitted light LL2.

The light reflected by the light adjustment member 40 can be reflected by the first wiring layer 22 and the support member 12, and can travel toward the light adjustment member 40 again. In such a case, since the light is transmitted through the light adjustment member 40 or reflected again depending on an incident angle to the light adjustment member 40, the distribution of luminance of actual emission from the light-emitting element 30 is determined in a more complicated situation.

In this way, the luminance of light immediately above the light-emitting element 30 is reduced, and the intensity of light in a peripheral portion immediately above the light-emitting element 30 is increased. The luminance of the light immediately above the light-emitting element 30 is determined by the light transmittance of the light adjustment member 40 and the degree of diffusion. Actually, since the light travels through the first light-transmissive member 60, the luminance of the light is attenuated according to a length of the optical path. The luminance of the light traveling through the first light-transmissive member 60 is further attenuated by reflection. Therefore, the luminance of light that is not transmitted through the light adjustment member 40, such as the lights LL2 and LL3, is lower than the luminance when the light is emitted from the light-emitting element 30. Accordingly, by appropriately setting the light transmittance of the light adjustment member 40, the distribution of the luminance of light emitted from a region between the inner wall surfaces 50W can be controlled, and the luminance unevenness of light above the light-emitting elements 30 can be reduced by appropriate control. Since the distribution of the luminance of the light emitted from the region between the inner wall surfaces 50W can also be controlled by adjusting the area of the light adjustment member 40 in XY plan view, the luminance unevenness of the light above the light-emitting elements 30 can be reduced.

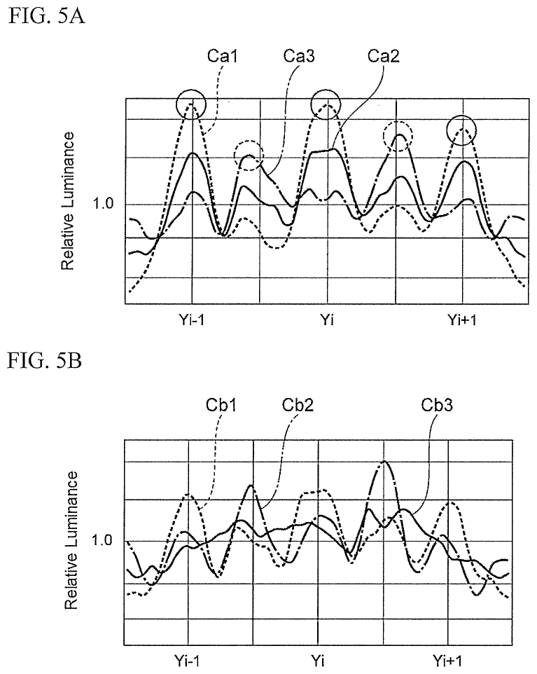

FIGS. 5A and 5B are schematic graphical representations for explaining the operation of the light-emitting module according to the first embodiment.

In order to consider the influence of luminance by adjacent light-emitting elements 30, the graphical representations of FIGS. 5A and 5B show a change in luminance depending on the positions of three light-emitting elements 30 when the light-emitting elements 30 are caused to emit light with the same luminance.

In FIGS. 5A and 5B, a horizontal axis represents the positions of the three light-emitting elements 30 in the Y-axis direction. In this example, the interval between the light-emitting elements 30 is uniform. Positions Yi−1, Yi, and Yi+1 in the Y-axis direction are coordinates of positions that bisect the length of the light-emitting element 30 in the Y-axis direction. In FIGS. 5A and 5B, a vertical axis represents relative luminance. In the graphical representations of FIGS. 5A and 5B, when the amplitude of each curve, that is, the difference between a minimum value and a maximum value is small in the Y-axis direction, luminance unevenness is small.

FIG. 5A is a graphical representation showing relative values of luminance levels in the Y-axis direction when the light transmittance of the light adjustment member 40 is changed. The thickness T2 of the light adjustment member 40 is adjusted such that the light transmittance decreases in the order of curves Ca1, Ca2, and Ca3 in FIG. 5A.

FIG. 5B is a graphical representation showing relative values of luminance in the Y-axis direction when the area of the light adjustment member 40 in plan view is changed. The shape of the light adjustment member 40 is adjusted such that the area of the light adjustment member 40 in plan view decreases in the order of curves Cb1, Cb2, and Cb3 in FIG. 5B. In the graphical representation of FIG. 5B, the light transmittance of the light adjustment member 40 is the same as that in the case of the curve Ca2 in the graphical representation of FIG. 5A.

As shown in FIG. 5A, in the curve Ca1, as indicated by solid circles in the graphical representation, the luminance at the positions where the light-emitting elements 30 are arranged is higher than the luminance at other positions. This is because the luminance of light transmitted through the light adjustment member 40 is not sufficiently reduced and is higher than the luminance of light emitted from the periphery of the light adjustment member 40.

On the other hand, in the curve Ca3, as indicated by broken-line circles in the graphical representation, the luminance is high at a substantially intermediate position between adjacent light-emitting elements 30. This is because light reflected by the light adjustment member 40 is emitted from the periphery of the light adjustment member 40 and the light and directly emitted light are intensified with each other to obtain high luminance.

In the curve Ca2, a change in the luminance of light is smaller in the Y-axis direction than in the other curves Ca1 and Ca3. That is, the luminance unevenness is smaller in the curve Ca2 than in the other curves.

As shown in FIG. 5B, in the curve Cb1, the amplitude of the relative luminance in the Y-axis direction is such that the luminance at the positions where the light-emitting elements 30 are arranged is higher than the luminance at other positions. In the curve Cb2, the amplitude of the relative luminance in the Y-axis direction is such that the luminance at a position between adjacent light-emitting elements 30 is high.

In the curve Cb3, the amplitude of the relative luminance in the Y-axis direction is sufficiently smaller than the amplitudes in the other curves Cb1 and Cb2.

Accordingly, by appropriately setting the light transmittance of the light adjustment member 40 and the area of the light adjustment member 40 in plan view, luminance unevenness of the light-emitting module 100 as a surface light source can be reduced. In a case in which the luminance of light immediately above the light-emitting element 30 is high, when light with high luminance is transmitted through the wavelength conversion member 70, light emitted by the light-emitting element 30 may be emitted with a strong color, and may be visually recognized as color unevenness of the light-emitting module 100. In the light-emitting module 100 of the present embodiment, the light adjustment member 40 is arranged above the light-emitting element 30 to reduce the luminance of light immediately above the light-emitting element 30, thereby reducing color unevenness of the light-emitting module 100.

Reduction of luminance unevenness of the light-emitting module 100 is not limited to adjustment of the transmittance and the area in XY plan view of the light adjustment member 40. A specific example for reducing the luminance unevenness of the light-emitting module 100 is described below.

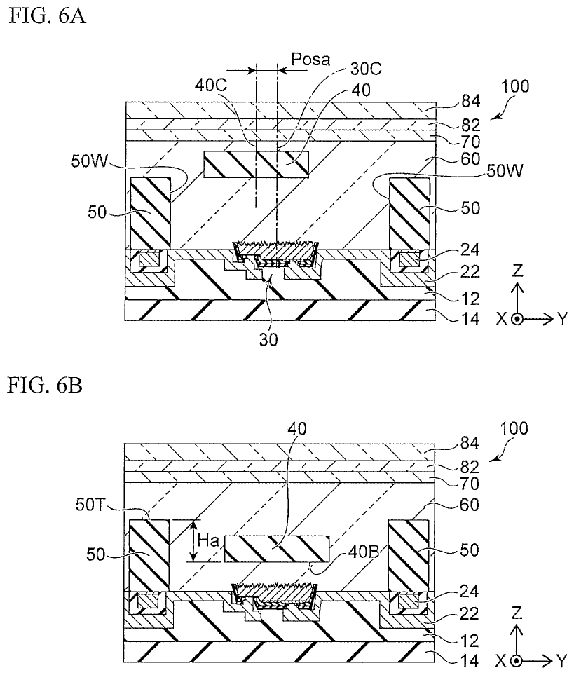

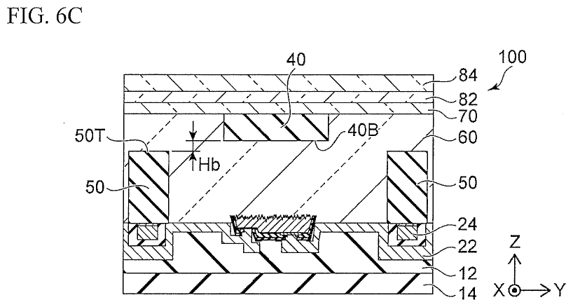

FIGS. 6A to 8 are schematic cross-sectional views illustrating the light-emitting module according to the first embodiment.

As illustrated in FIG. 6A, in XY plan view, the light adjustment member 40 can be arranged at a position shifted from a position directly above the light-emitting elements 30.

Specifically, the position of a bisector 40C of the length of the light adjustment member 40 in the Y-axis direction is shifted by Posa in the negative direction of the Y-axis from the position of a bisector 30C of the length of the light-emitting element 30 in the Y-axis direction. It is assumed that the position of the bisector 30C of the light-emitting element 30 coincides with the position of a bisector of a length in the Y-axis direction between two inner wall surfaces 50W between which the light-emitting element 30 is sandwiched. The positional deviation between the light adjustment member 40 and the light-emitting element 30 is not limited to that in the Y-axis direction, and the position may be shifted to an arbitrary position in the XY plane. When the region surrounded by the outer periphery of the light adjustment member 40 and the region surrounded by the outer periphery of the light-emitting element 30 in plan view are substantially square as in this example, the bisectors 40C and 30C are straight lines passing through the intersections of diagonal lines of the corresponding squares. When the region surrounded by the outer periphery of the light adjustment member 40 and the region surrounded by the outer periphery of the light-emitting element 30 in plan view have an arbitrary polygonal shape, circular shape, elliptical shape, or the like, the bisectors 40C and 30C are straight lines passing through the centers of gravity of these regions.

The relative positions of the light adjustment member 40 and the light-emitting element 30 in XY plan view are set the same over the entire surface of the light-emitting module 100, for example. The relative position between the light adjustment member 40 and the light-emitting element 30 can be set in accordance with the position of the light-emitting element 30 in the light-emitting module 100 such that luminance unevenness in the light-emitting module 100 is reduced.

As illustrated in FIGS. 6B and 6C, the position of the light adjustment member 40 in the Z-axis direction is not limited to that in the case in which the position of the lower surface 40B of the light adjustment member 40 in the Z-axis direction coincides with the position of the upper surface 50T of the light-shielding member 50 in the Z-axis direction. In FIG. 6B, the position of the lower surface 40B of the light adjustment member 40 in the Z-axis direction is lower than the position of the upper surface 50T of the light-shielding member 50 in the Z-axis direction. A difference Ha in the position in the Z-axis direction has a negative value when the position of the upper surface 50T of the light-shielding member 50 in the Z-axis direction is used as a reference. In FIG. 6C, the position of the lower surface 40B of the light adjustment member 40 in the Z-axis direction is higher than the position of the upper surface 50T of the light-shielding member 50 in the Z-axis direction. A difference Hb in the position in the Z-axis direction has a positive value when the position of the upper surface 50T of the light-shielding member 50 in the Z-axis direction is used as a reference.

The position of the light adjustment member 40 in the Z-axis direction is appropriately set in accordance with the materials, dimensions, and the like of the light adjustment member 40, the light-shielding member 50, and the first light-transmissive member 60.

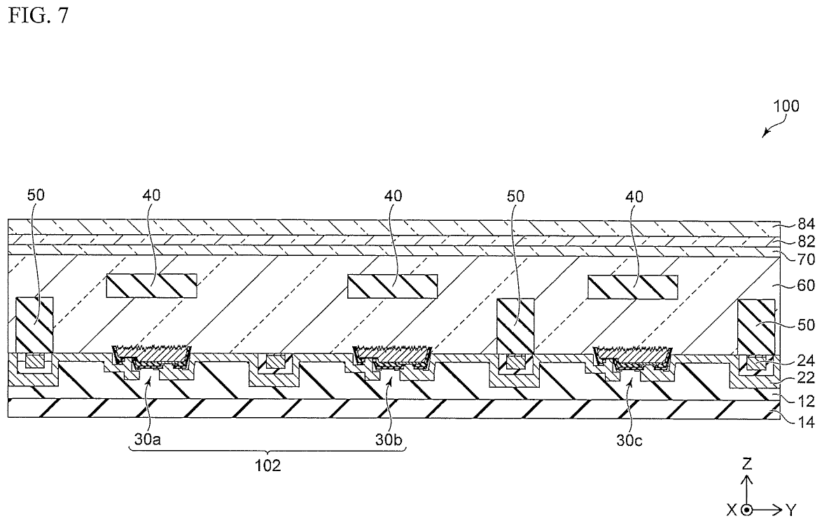

As illustrated in FIG. 7, the light-emitting module 100 can include a segment 102. The segment 102 includes a plurality of light-emitting elements 30a and 30b. The plurality of light-emitting elements 30a and 30b constituting the segment 102 are surrounded by the light-shielding member 50 in XY plan view. The segment 102 serves as one light source.

Since the light-shielding member 50 surrounds the two light-emitting elements 30a and 30b, no light-shielding member is arranged between the light-emitting element (first light-emitting element) 30a and the light-emitting element 30b. A light-emitting element 30c adjacent to the light-emitting element 30b constitutes a different segment. The light-shielding member 50 is arranged between the light-emitting element (third light-emitting element) 30b and the light-emitting element (second light-emitting element) 30c. Three light adjustment members 40 are spaced apart from the light-emitting elements 30a, 30b, and 30c in the Z-axis direction, respectively. The light-emitting elements 30a, 30b, and 30c are denoted by different reference characters in order to distinguish the three light-emitting elements from one another in terms of arrangement positions thereof, and the light-emitting elements 30a, 30b, and 30c are elements having the same shape and the same characteristics as the light-emitting elements 30.

In addition to the above, when the second wiring layer 24 does not exist between adjacent light-emitting elements 30, since no target to be covered by the light-shielding member 50 exists, the light-shielding member 50 is not necessarily formed. In this case, a process of forming the light-shielding member 50 can be simplified.

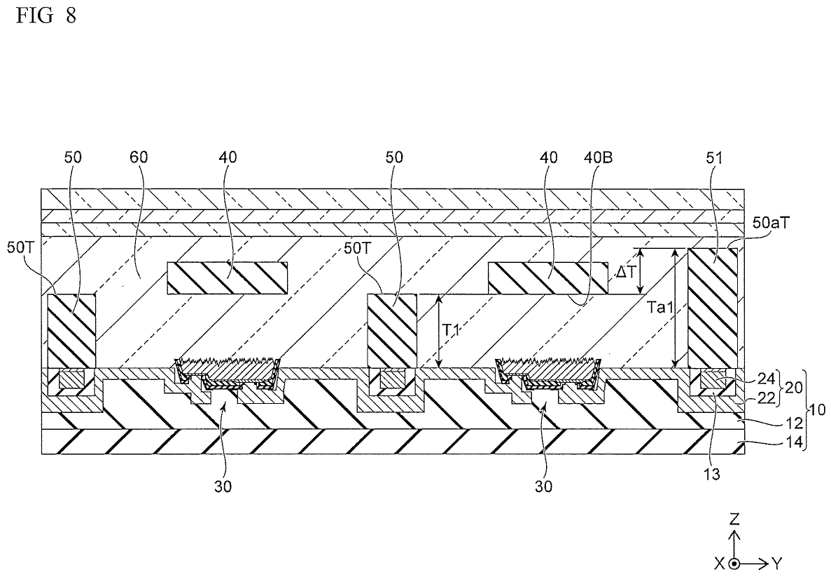

As illustrated in FIG. 8, the thickness of the light-shielding member 50 is not limited to the case in which the thickness is uniform, and for example, the thickness of the light-shielding member 50 can be varied according to the arrangement position. In this example, two light-emitting elements 30 are illustrated, and one of the light-emitting elements 30 is arranged between light-shielding members 50 having the same thickness. The other light-emitting element 30 is arranged between light-shielding members 50 and 51 having different thicknesses.

The thickness T1 of the light-shielding member 50 is a length along the Z-axis direction from the first surface 12a to the upper surface 50T. A thickness Ta1 of the light-shielding member 51 is a length along the Z-axis direction from the first surface 12a to an upper surface 50aT of the light-shielding member 51. The thickness Ta1 is thicker than the thickness T1 by ΔT. For example, since no adjacent light-emitting elements 30 exist at corners and sides in the plane of the light-emitting module 100, light emitted by the light-emitting elements 30 can be prevented from leaking by making the thickness Ta1 of the light-shielding member 51 thicker than the thicknesses at other portions. In this way, by making the thicknesses of the light-shielding members 50 and 51 vary according to the arrangement positions on the XY plane, the luminance unevenness of light emitted by the light-emitting module 100 can be reduced.

### First to Seventh Modified Examples

In the light-emitting module 100 according to the first embodiment, both the shape of the region surrounded by the outer periphery of the light adjustment member 40 and the shape of the region surrounded by the inner periphery of the inner wall surface 50W of the light-shielding member 50 are substantially square in XY plan view. The shape is not limited thereto and can be any appropriate shape as long as luminance unevenness of light emitted from the light-emitting module 100 can be reduced. Configurations of modified examples of the shape of the region surrounded by the outer periphery of the light adjustment member and the shape of the region surrounded by the inner periphery of the inner wall surface in XY plan view are described below.

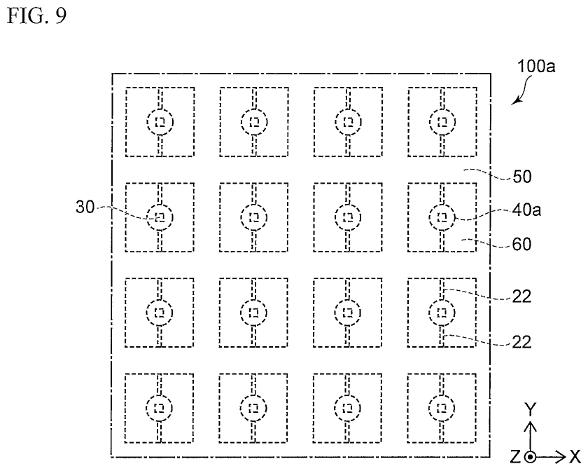

FIGS. 9 to 13 are schematic top views illustrating first to seventh modified examples of the light-emitting module according to the first embodiment.

As illustrated in FIG. 9, a light-emitting module 100a according to the first modified example includes a plurality of light adjustment members 40a instead of the plurality of light adjustment members 40 illustrated in FIG. 2. The shape of a region surrounded by an outer periphery of each of the plurality of light adjustment members 40a is circular in XY plan view. The light adjustment member 40a can be formed of the same material as the material of the light adjustment member 40 in the light-emitting module 100 of the first embodiment. The light adjustment member can have an elliptical shape in accordance with the distribution of the luminance of light emitted from the light-emitting element 30, or the like.

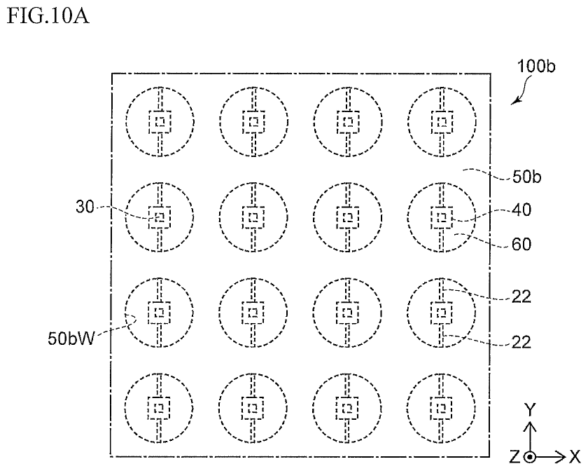

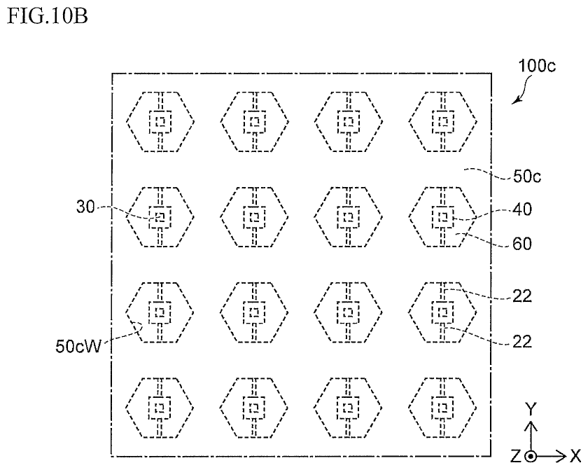

As illustrated in FIG. 10A, a light-emitting module 100b according to the second modified example includes a light-shielding member 50b instead of the light-shielding member 50 illustrated in FIG. 2. In XY plan view, the shape of a region surrounded by an inner periphery of an inner wall surface 50bW of the light-shielding member 50b is circular. The light-emitting element 30 and the light adjustment member 40 are surrounded by the circular inner wall surface 50bW in XY plan view. The shape of the region surrounded by the inner periphery of the inner wall surface 50bW in XY plan view can be an elliptical shape instead of a circular shape in accordance with the distribution of the luminance of light emitted from the light-emitting element 30, or the like.

As illustrated in FIG. 10B, a light-emitting module 100c according to the third modified example includes a light-shielding member 50c instead of the light-shielding member 50 illustrated in FIG. 2. In XY plan view, the shape of a region surrounded by an inner periphery of an inner wall surface 50cW of the light-shielding member 50c is a regular hexagon. The light-emitting element 30 and the light adjustment member 40 are surrounded by the inner wall surface 50cW having a regular hexagonal shape, in XY plan view. The shape of the region surrounded by the inner periphery of the inner wall surface 50cW in XY plan view is not limited to a regular hexagon and can be any hexagon or any polygon such as a triangle or a quadrangle in accordance with the distribution of the luminance of light emitted from the light-emitting element 30, or the like.

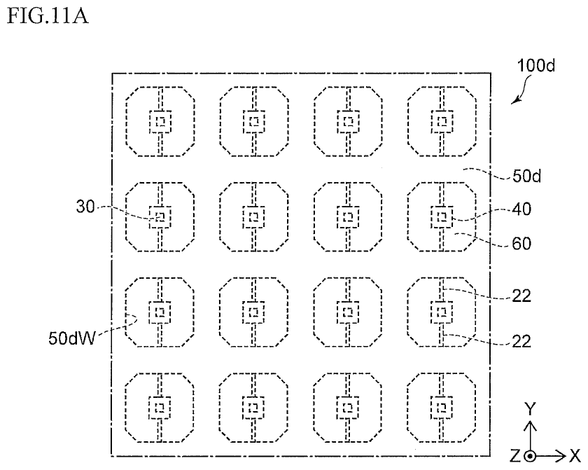

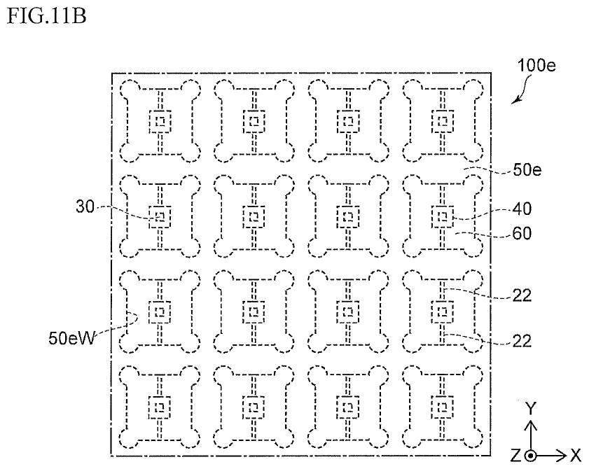

As illustrated in FIG. 11A, a light-emitting module 100d according to the fourth modified example includes a light-shielding member 50d instead of the light-shielding member 50 illustrated in FIG. 2. In XY plan view, the shape of a region surrounded by an inner periphery of an inner wall surface 50dW of the light-shielding member 50d is an octagon in which the corners of a square are chamfered. The light-emitting element 30 and the light adjustment member 40 are surrounded by the octagonal inner wall surface 50dW in XY plan view. In the shape of the region surrounded by the inner periphery of the inner wall surface 50dW in XY plan view, the degree of chamfering of the corners can be arbitrarily set in accordance with the distribution of the luminance of light emitted from the light-emitting element 30, or the like.

As illustrated in FIG. 11B, a light-emitting module 100e according to the fifth modified example includes a light-shielding member 50e instead of the light-shielding member 50 illustrated in FIG. 2. In XY plan view, the shape of a region surrounded by an inner periphery of an inner wall surface 50eW of the light-shielding member 50e is a shape obtained by cutting out four corners of a square into a circular shape. The light-emitting element 30 and the light adjustment member 40 are surrounded by the inner wall surface 50eW having a shape obtained by cutting out the four corners of the square into a circular shape in XY plan view. In the shape of the region surrounded by the inner periphery of the inner wall surface 50eW, the shape formed by cutting out the corners can be an arbitrary figure shape other than a circle in accordance with the distribution of the luminance of light emitted from the light-emitting element 30, or the like.

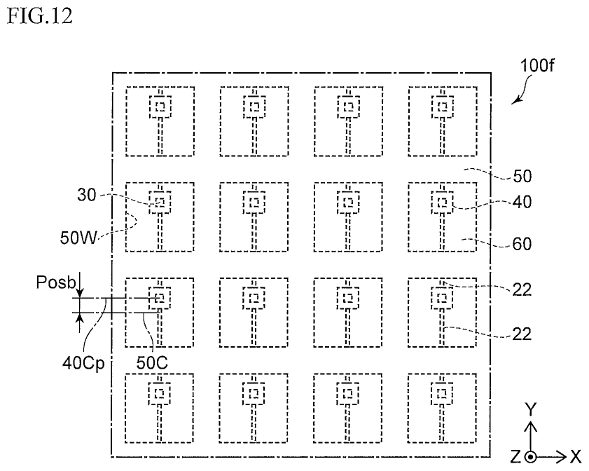

As illustrated in FIG. 12, a light-emitting module 100f according to the sixth modified example is different from the light-emitting module 100 illustrated in FIGS. 2 and 6A in the arrangement of the light-emitting elements 30 and the light adjustment members 40 in XY plan view. In the present modified example, the positions of centers of the light-emitting element 30 and the light adjustment member 40 coincide with each other in XY plan view. The light-emitting element 30 and the light adjustment member 40 are arranged such that the position of a coincident center 40Cp of the light-emitting element 30 and the light adjustment member 40 is shifted from the position of a center 50C of the region surrounded by the inner periphery of the inner wall surface 50W of the light-shielding member 50 in XY plan view. In this example, the position of the center 40Cp of the light-emitting element 30 and the light adjustment member 40 is shifted in the positive direction of the Y-axis by Posb from the position of the center 50C of the region surrounded by the inner periphery of the inner wall surface 50W. The position of the center 40Cp can be arbitrarily shifted in an appropriate direction from the position of the center 50C in accordance with the distribution of the luminance of light emitted from the light-emitting element 30, or the like. For example, the shift position and the shift amount of the center 40Cp with respect to the center 50C can be the same over the entire plane of the light-emitting module 100, or the shift amount can be different for each region in the plane of the light-emitting module 100 or can be different for each light-emitting element 30.

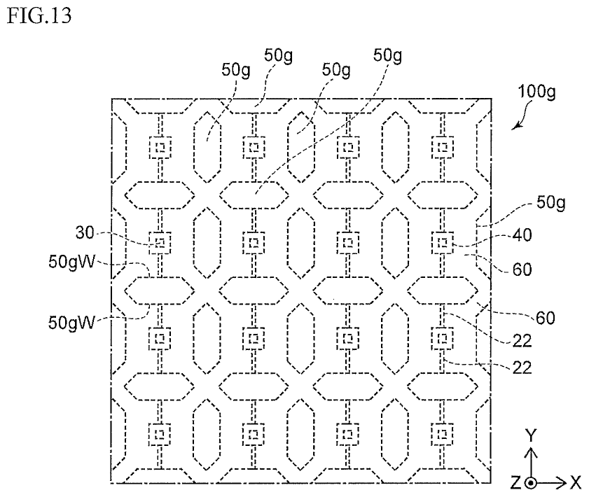

As illustrated in FIG. 13, a light-emitting module 100g according to the seventh modified example includes a light-shielding member 50g instead of the light-shielding member 50 illustrated in FIG. 2. In the present modified example, a plurality of light-shielding members 50g surround the light-emitting elements 30 and the light adjustment member 40 in XY plan view. In this example, four light-shielding members 50g surround one set of the light-emitting element 30 and the light adjustment member 40. One light-shielding member 50g is arranged between two adjacent light-emitting elements 30. The light-shielding member 50g arranged between the two light-emitting elements 30 has an inner wall surface 50gW facing one of the light-emitting elements 30, and faces the other of the light-emitting elements 30 on an inner wall surface 50gW opposite to the inner wall surface 50gW.

In XY plan view, two adjacent light-shielding members 50g are separated from each other, and the first light-transmissive member 60 is arranged between the two light-shielding members 50g. The first light-transmissive member 60 covers the plurality of light-shielding members 50g together with the light-emitting elements 30 and the light adjustment members 40. The shape of the light-shielding member 50g in XY plan view, the separation distance between adjacent light-shielding members 50g, the number of light-shielding members 50g surrounding the light adjustment member 40, and the like can be changed in accordance with the distribution of the luminance of light emitted from the light-emitting element 30, or the like.

The first to seventh modified examples described above can be combined with one another. For example, the circular light adjustment member 40a illustrated in FIG. 9 can be combined with the light-shielding member 50b illustrated in FIG. 10A, or can be combined with a light-shielding member having an inner periphery of an inner wall surface having another shape. When the above-described modified examples are combined, not only two types of modified examples but also three or more types of modified examples can be combined. For example, after the circular light adjustment member 40a illustrated in FIG. 9 is combined with the light-shielding member 50b having the inner periphery of the circular inner wall surface illustrated in FIG. 10A, the centers of the light-emitting element 30 and the light adjustment member 40a can be shifted from the center of the inner periphery of the inner wall surface as illustrated in FIG. 12.

The first to seventh modified examples described above can also be applied to other embodiments to be described below.

Effects of the light-emitting module 100 according to the present embodiment and the modified examples thereof are described.

In the following description, it is assumed that the light adjustment member includes the light adjustment member 40 in the first embodiment and the light adjustment member 40a in each modified example, and the light-shielding member includes the light-shielding members 50 and 51 in the first embodiment and the light-shielding members 50b to 50e and 50g in the modified examples.

The light-emitting module 100 according to the present embodiment and the modified examples thereof includes a plurality of light adjustment members spaced apart from the upper surfaces of the respective plurality of light-emitting elements 30. The light adjustment member transmits a part of light from the light-emitting element 30 and reflects the other part thereof. The light adjustment member weakens the luminance of a part of the incident light and emits the light. Therefore, by arranging the light adjustment member, the luminance immediately above the light-emitting element 30 is weakened, contributing to reduction in luminance unevenness above the light-emitting element 30.

The light transmittance of the light adjustment member can be adjusted by adjusting the material of the light adjustment member or the thickness of the light adjustment member. Therefore, the light transmittance of the light adjustment member can be easily set in accordance with the distance between the light-emitting element 30 and the light adjustment member, or the like.

The light adjustment member can contain a light diffusion filler or the like. The light adjustment member having a light diffusion function can diffuse incident light to obtain a substantially uniform luminance distribution on an upper surface of the light adjustment member. Therefore, by arranging such a light adjustment member, the luminance unevenness above the light-emitting element 30 can be further reduced.

The light-emitting module 100 includes a light-shielding member that surrounds the light-emitting element 30 and is arranged between the light-emitting element 30 and another light-emitting element 30 in XY plan view. In XY plan view, the light-shielding member blocks light emitted from the light-emitting element 30 surrounded by the light-shielding member. Therefore, light emitted by the light-emitting element 30 surrounded by an inner periphery of the light-shielding member is emitted to above a region surrounded by the inner periphery of the light-shielding member in XY plan view. Therefore, interference from light emitted by another adjacent light-emitting element 30 blocked by the light-shielding member can be reduced. Accordingly, by arranging the light-shielding member, the luminance of light emitted from a region between the light adjustment member and an inner wall surface in XY plan view can be appropriately adjusted.

In XY plan view, the luminance of light emitted from the region between the light adjustment member 40 and the inner wall surface 50W can be controlled by the shape and area of the region. The shape of the outer periphery of the light adjustment member 40 and the area surrounded by the outer periphery in XY plan view can be set, and the shape of the region surrounded by the inner periphery of the inner wall surface 50W and the area of the region in XY plan view can be set. This makes it possible to reduce luminance unevenness above the light-emitting element 30.

The relative positions in the Z-axis direction between the light adjustment member and the light-shielding member, the thicknesses of the light-shielding members, and the like may also affect the distribution of the luminance of light emitted from the region between the light adjustment member 40 and the inner wall surface 50W in XY plan view. In the light-emitting module 100 of the present embodiment and each modified example thereof, these parameters can be easily set, and by appropriately setting these parameters, luminance unevenness above the light-emitting element 30 can be reduced.

### Second Embodiment

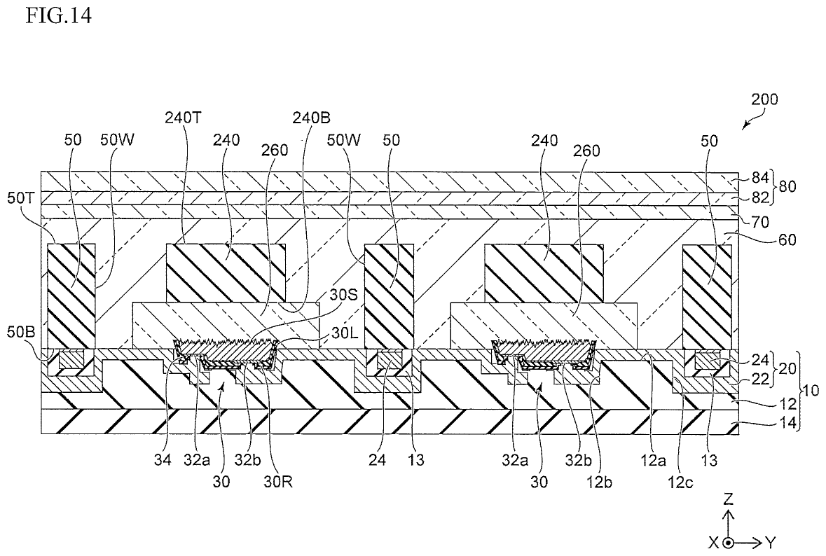

FIG. 14 is a schematic cross-sectional view illustrating a light-emitting module according to a second embodiment.

In a light-emitting module 200 according to the present embodiment, a plurality of light-emitting elements 30 are arranged in a matrix as in the light-emitting module 100 illustrated in FIG. 1. FIG. 14 is a cross-sectional view corresponding to the cross-sectional view taken along line III-III in FIG. 1.

As illustrated in FIG. 14, the light-emitting module 200 according to the present embodiment includes a light adjustment member 240 and further includes a second light-transmissive member 260. The light-emitting module 200 of the present embodiment is different from the light-emitting module 100 of the first embodiment in that the configuration of the light adjustment member 240 is different from the configuration of the light adjustment member 40 of the first embodiment. The light-emitting module 200 of the present embodiment is also different from the first embodiment in that the light-emitting module 200 includes the second light-transmissive member 260. In other aspects, the light-emitting module 200 of the present embodiment is the same as the light-emitting module 100 of the first embodiment, and the same components are denoted by the same reference characters and detailed description thereof is omitted as appropriate.

The second light-transmissive member 260 is arranged between the light adjustment member 240 and the light-emitting element 30. The second light-transmissive member 260 is arranged on the first surface 12a, the first wiring layer 22, and the light-emitting element 30. The second light-transmissive member 260 is in contact with a lower surface 240B of the light adjustment member 240. The light extraction surface 30S of the light-emitting element 30 is in contact with the second light-transmissive member 260, and the second light-transmissive member 260 covers the light extraction surface 30S. A portion of the lateral surface 30L of the light-emitting element 30 that is not embedded in the recessed portion 12b is in contact with the second light-transmissive member 260, and the second light-transmissive member 260 covers the lateral surface 30L that is not embedded in the recessed portion 12b.

In XY plan view, a region surrounded by an outer periphery of the second light-transmissive member 260 is arranged inside the region surrounded by the inner periphery of the inner wall surface 50W. That is, a length of the second light-transmissive member 260 in the Y-axis direction is shorter than a distance between opposing inner wall surfaces 50W spaced apart from each other in the Y-axis direction, and a length of the second light-transmissive member 260 in the X-axis direction is shorter than a distance between the opposing inner wall surfaces spaced apart from each other in the X-axis direction.

The light adjustment member 240 is arranged on the second light-transmissive member 260. The light adjustment member 240 is arranged such that the position of an upper surface 240T of the light adjustment member 240 in the Z-axis direction substantially coincides with the position of the upper surface 50T of the light-shielding member 50 in the Z-axis direction. That is, the sum of a thickness of the second light-transmissive member 260 and a thickness of the light adjustment member 240 is substantially equal to the thickness of the light-shielding member 50.

As in the first embodiment, a region surrounded by an outer periphery of the light adjustment member 240 overlaps at least a part of the region surrounded by the outer periphery of the light-emitting element 30 in XY plan view. In the example illustrated in FIG. 14, the outer periphery of the light adjustment member 240 is arranged on an outer side of the outer periphery of the light-emitting element 30 in XY plan view. That is, in XY plan view, the region surrounded by the outer periphery of the light adjustment member 240 completely overlaps the region surrounded by the outer periphery of the light-emitting element 30.

The first light-transmissive member 60 is arranged between the second light-transmissive member 260 and the light-shielding member 50. The first light-transmissive member 60 covers the first surface 12a, the first wiring layer 22, the light-shielding member 50, the second light-transmissive member 260, and the light adjustment member 240. As in the first embodiment, the wavelength conversion member 70 and the optical member 80 are arranged on the first light-transmissive member 60.

The light adjustment member 240 is formed of a material similar to the material in the first embodiment, and is preferably formed of the same material as the material of the light-shielding member 50 as in the first embodiment.

The second light-transmissive member 260 can have optical characteristics different from the optical characteristics of the first light-transmissive member 60. The optical characteristics are, for example, a light transmittance, a light refractive index, and the like.

The second light-transmissive member 260 is, for example, a light-transmissive adhesive sheet. The second light-transmissive member 260 is a double-sided adhesive sheet. The second light-transmissive member 260 is cut to an appropriate dimension in plan view and attached onto the light-emitting element 30. The lower surface 240B of the light adjustment member 240 is attached to a surface of the second light-transmissive member 260 opposite to the surface attached to the light-emitting element 30. The second light-transmissive member 260 is, for example, a light-transmissive resin layer, and can be a layer obtained by solidifying a light-transmissive adhesive layer.

### Modified Example

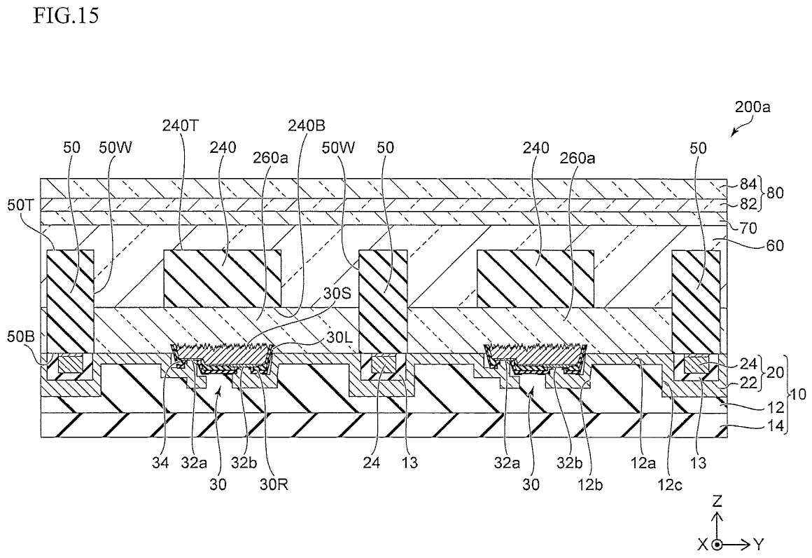

FIG. 15 is a schematic cross-sectional view illustrating a light-emitting module according to a modified example of the second embodiment.

As illustrated in FIG. 15, in the present modified example, a second light-transmissive member 260a is provided in contact with the inner wall surfaces 50W of the light-shielding members 50 surrounding the light-emitting elements 30. The second light-transmissive member 260a covers the first surface 12a, the first wiring layer 22, and the light-emitting elements 30. The first light-transmissive member 60 covers the second light-transmissive member 260a, the light-shielding members 50, and the light adjustment members 240. In XY plan view, an outer periphery of the second light-transmissive member 260a substantially coincides with the inner periphery of the inner wall surface 50W.

The light-emitting modules 200 and 200a according to the present embodiment and the modified example thereof can reduce the luminance unevenness of light above the light-emitting elements 30 by balancing the luminance of light transmitted through the light adjustment member 240 and the luminance of light emitted from the periphery of the light adjustment member 240. The means for balancing the luminances of lights in different paths is the same as that in the first embodiment.

Effects of the light-emitting modules 200 and 200a according to the present embodiment and the modified example thereof are described.

The light-emitting modules 200 and 200a according to the present embodiment and the modified example thereof have the same effects as the first embodiment described above. In addition, the following effects are achieved.

The light-emitting modules 200 and 200a according to the present embodiment and the modified example thereof include the second light-transmissive members 260 and 260a each arranged between the light adjustment member 240 and the light-emitting element 30, respectively. The second light-transmissive members 260 and 260a can have optical characteristics different from the optical characteristics of the first light-transmissive member 60. When the light transmittances of the second light-transmissive members 260 and 260a are set lower than the light transmittance of the first light-transmissive member 60, the luminance of light traveling from the light-emitting elements 30 toward the light adjustment member 240 can be reduced in advance. This allows the distribution of the luminance above the light-emitting elements 30 to be appropriately adjusted.

In the light-emitting module 200a of the modified example, light incident on the first light-transmissive member 60 is light emitted from the second light-transmissive member 260a. The refractive index of the first light-transmissive member 60 and the refractive index of the second light-transmissive member 260a can be appropriately set. This enables adjustment of the light distribution of light emitted from a region between the light adjustment member 240 and the inner wall surface 50W of the light-shielding member 50 in XY plan view. Accordingly, the distribution of the luminance of the light emitted from the region between the light adjustment member 240 and the inner wall surface 50W of the light-shielding member 50 can be more appropriately adjusted.

A light-transmissive member where a fine shape can be formed using a photolithography technique can be used for the second light-transmissive members 260 and 260a. In such a case, the second light-transmissive members 260 and 260a having a fine shape can be formed when the light-emitting modules 200 and 200a are manufactured, respectively. Therefore, the distance between adjacent light-emitting elements 30 can be shortened, so that the light-emitting module can be further miniaturized. Sheet-like members having light-transmissive properties and adhesive properties can also be used for the second light-transmissive members 260 and 260a, and these members can be selectively used in accordance with the shape and size of the light-emitting modules 200 and 200a.

The second light-transmissive members 260 and 260a can have a uniform thickness. The second light-transmissive members 260 and 260a can be formed by placing an adhesive material on both sides of a base material. Therefore, by providing the second light-transmissive member 260 or 260a between the light adjustment member 240 and the light-emitting element 30, the separation distance between the light adjustment member 240 and the light-emitting element 30 can be easily adjusted to a desired value.

### Third Embodiment

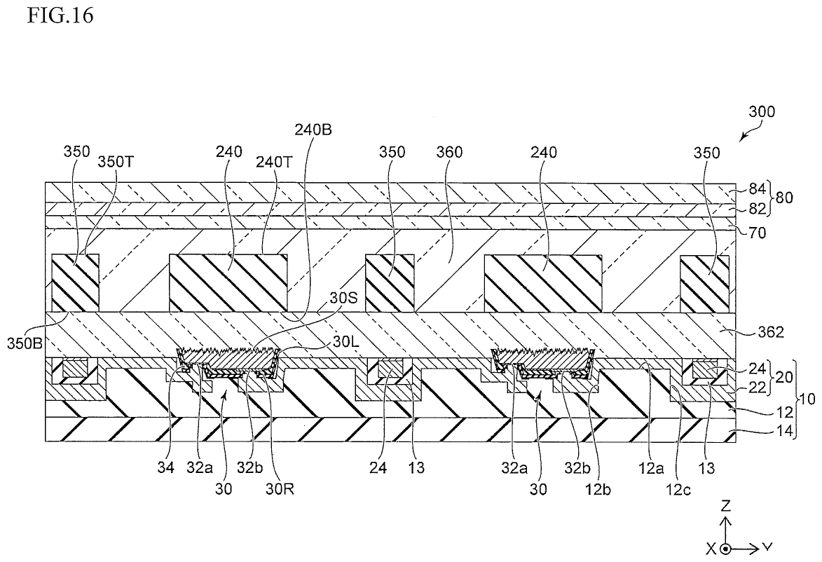

FIG. 16 is a schematic cross-sectional view illustrating a light-emitting module according to a third embodiment.

As illustrated in FIG. 16, a light-emitting module 300 according to the present embodiment is different from the light-emitting module 100 of the first embodiment in that the light-emitting module 300 includes a second light-transmissive member 362. In the light-emitting module 300, the configuration of a first light-transmissive member 360 is different from the configuration of the first light-transmissive member 60 of the light-emitting module 100 of the first embodiment. In the light-emitting module 300 of the present embodiment, the configuration of a light-shielding member 350 is different from the configuration of the light-shielding member in the first embodiment. The other configurations are the same as the configurations in the other embodiments described above, and the same components are denoted by the same reference characters and detailed description thereof is omitted as appropriate.

The second light-transmissive member 362 is arranged on the first surface 12a, the first wiring layer 22, and the light-emitting elements 30. The second light-transmissive member 362 covers the first surface 12a, the first wiring layer 22, and the light-emitting elements 30. As in the second embodiment, the light extraction surface 30S of the light-emitting element 30 is in contact with the second light-transmissive member 362, and the second light-transmissive member 362 covers the light extraction surface 30S. As in the second embodiment, a portion of the lateral surface 30L of the light-emitting element 30 that is not embedded in the recessed portion 12b is in contact with the second light-transmissive member 362, and the second light-transmissive member 362 covers the lateral surface 30L that is not embedded in the recessed portion 12b.

The second light-transmissive member 362 has optical characteristics different from the optical characteristics of the first light-transmissive member 360. The optical characteristics are, for example, a light transmittance, a light refractive index, and the like.

The second light-transmissive member 362 is, for example, a light-transmissive adhesive sheet. The second light-transmissive member 362 is, for example, a light-transmissive resin layer, and can be a layer obtained by solidifying a light-transmissive adhesive layer. Such a second light-transmissive member 362 can be made of the same material as the material of the second light-transmissive member 260 of the light-emitting module 200 of the second embodiment.

The light adjustment member 240 is arranged on the second light-transmissive member 362. The light adjustment member 240 is in contact with the second light-transmissive member 362 at the lower surface 240B, and the light adjustment member 240 is arranged on the light-emitting elements 30 via the second light-transmissive member 362. In plan view, the region surrounded by the outer periphery of the light adjustment member 240 overlaps at least a part of the region surrounded by the outer periphery of the light-emitting element 30.

The light-shielding member 350 is arranged on the second light-transmissive member 362. The light-shielding member 350 is in contact with the second light-transmissive member 362 at a lower surface 350B thereof. The light-shielding member 350 is arranged on the second wiring layer 24 via the second light-transmissive member 362.

The light-shielding member 350 is formed of a material having a light-blocking property against light emitted from the light-emitting element 30. Preferably, the light-shielding member 350 is formed of a light-reflective resin. The same material as the material of the light-shielding member 50 of the light-emitting module 100 of the first embodiment can be used for the light-reflective resin. For example, a silicone resin, an epoxy resin, or the like can be suitably used, and when the light-reflective resin is formed of a material that absorbs light, a black resin can be used.

The thickness of the second light-transmissive member 362 is substantially uniform, and the position of the lower surface 240B of the light adjustment member 240 in the Z-axis direction is substantially the same as the position of the lower surface 350B of the light-shielding member 350 in the Z-axis direction. The thickness of the light adjustment member 240 and the thickness of the light-shielding member 350 are substantially the same, and the position of the upper surface 240T of the light adjustment member 240 in the Z-axis direction is substantially the same as the position of an upper surface 350T of the light-shielding member 350 in the Z-axis direction.

The first light-transmissive member 360 covers the second light-transmissive member 362, the light adjustment member 240, and the light-shielding member 350. A light-transmissive resin, for example, an epoxy resin, a silicone resin, or a resin in which these resins are mixed, glass, or the like can be used for the first light-transmissive member 360, and the same material as the material of the first light-transmissive member 60 of the light-emitting module 100 of the first embodiment can be used.

The wavelength conversion member 70 and the optical member 80 are arranged on the first light-transmissive member 360.

The light-emitting module 300 of the present embodiment operates like the light-emitting modules 100 and 200 of the other embodiments described above. That is, a part of light emitted from the light-emitting element 30 is emitted through the light adjustment member 240, and the other part thereof is emitted from the periphery of the light adjustment member 240. By adjusting the intensity balance between the luminance of the light emitted through the light adjustment member 240 and the luminance of the light emitted from the periphery of the light adjustment member 240, the luminance unevenness of light above the light-emitting element 30 can be reduced. The light-shielding member 350 is provided to adjust interference of light from another light-emitting element 30 provided across the light-shielding member 350. In the present embodiment, the luminance balance is adjusted in consideration of mixing of light from another light-emitting element 30 via the second light-transmissive member 362.

Effects of the light-emitting module 300 according to the present embodiment are described.

The light-emitting module 300 according to the present embodiment has the same effects as the first embodiment described above. In addition, the following effects are achieved.

In the light-emitting module 300 according to the present embodiment, the second light-transmissive member 362 covers the first surface 12a, the first wiring layer 22, and the light-emitting elements 30. The light adjustment member 240 is arranged over the light-emitting element 30 via the second light-transmissive member 362. Controlling the thickness of the second light-transmissive member 362 to be substantially uniform is easy, and the separation distance between the light-emitting element 30 and the light adjustment member 240 can be easily set. Therefore, the luminance when a part of light emitted from the light-emitting element 30 is incident on the light adjustment member 240 is easily adjusted.

In the light-emitting module 300 of the present embodiment, the second light-transmissive member 362 can be formed using the same material as the materials of the second light-transmissive members 260 and the 260a in the second embodiment. When the second light-transmissive member 362 is a member having adhesive properties, the light adjustment member 240 is easily arranged above the light-emitting element 30 so as to be spaced apart therefrom. In addition, the light-shielding member 350 can be arranged at the same time as when the light adjustment member 240 is arranged, so that the manufacturing process of the light-emitting module 300 can be simplified.

The second light-transmissive member 362 has optical characteristics different from the optical characteristics of the first light-transmissive member 360. By appropriately setting the refractive index of the second light-transmissive member 362 and the refractive index of the first light-transmissive member 360, light traveling toward the lower surface 350B of the light-shielding member 350 can be made difficult to be emitted toward adjacent light-emitting elements 30. Therefore, even though the light-shielding member 350 and the first surface 12a are spaced apart from each other, light emitted from the light-emitting element 30 surrounded by the light-shielding member 350 can be suppressed from interfering with light of adjacent light-emitting elements 30 in XY plan view.

Since the second light-transmissive member 362 is arranged between the light adjustment member 240 and the light-emitting element 30, the distribution of the luminance above the light-emitting element 30 can be finely controlled, as in the second embodiment.

### Fourth Embodiment

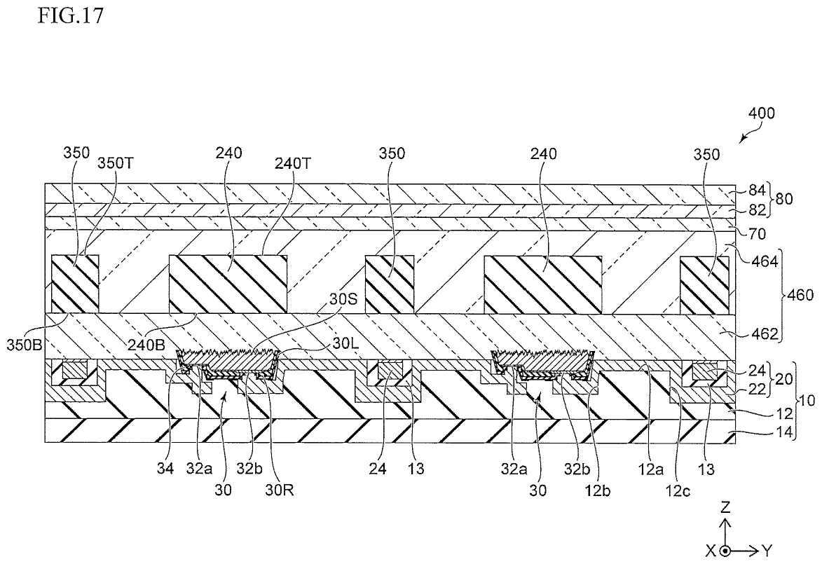

FIG. 17 is a schematic cross-sectional view illustrating a light-emitting module according to a fourth embodiment.

As illustrated in FIG. 17, a light-emitting module 400 according to the present embodiment is different from the light-emitting module 100 of the first embodiment in that the light-emitting module 400 includes a first light-transmissive member 460. In the light-emitting module 400, the configuration of the light adjustment member 240 is the same as the configuration of the light adjustment member in the second embodiment, and the configuration of the light-shielding member 350 is the same as the configuration of the light-shielding member in the third embodiment. The other configurations are the same as the configurations in the other embodiments, and the same components are denoted by the same reference characters and detailed description thereof is omitted as appropriate.

The first light-transmissive member 460 includes a first portion 462 and a second portion 464. The first portion 462 is arranged on the first surface 12a, the first wiring layer 22, and the light-emitting elements 30. The first portion 462 covers the first surface 12a, the first wiring layer 22, and the light-emitting elements 30. The light extraction surface 30S of the light-emitting element 30 is in contact with the first portion 462, and the first portion 462 covers the light extraction surface 30S. A portion of the lateral surface 30L of the light-emitting element 30 that is not embedded in the recessed portion 12b is in contact with the first portion 462, and the first portion 462 covers the lateral surface 30L that is not embedded in the recessed portion 12b.

The light adjustment member 240 is arranged on the first portion 462. The light adjustment member 240 is in contact with the first portion 462 at the lower surface 240B, and is arranged over the light-emitting element 30 via the first portion 462. In plan view, the region surrounded by the outer periphery of the light adjustment member 240 overlaps at least a part of the region surrounded by the outer periphery of the light-emitting element 30.

The light-shielding member 350 is arranged on the first portion 462. The light-shielding member 350 is in contact with the first portion 462 at the lower surface 350B. The light-shielding member 350 is arranged over the second wiring layer 24 via the first portion 462.

The thickness of the first portion 462 can vary depending on the position in plan view, for example. In this example, the thickness of the first portion 462 is substantially uniform, and the position of the lower surface 240B of the light adjustment member 240 in the Z-axis direction is substantially the same as the position of the lower surface 350B of the light-shielding member 350 in the Z-axis direction. The thickness of the light adjustment member 240 and the thickness of the light-shielding member 350 are substantially the same, and the position of the upper surface 240T of the light adjustment member 240 in the Z-axis direction is substantially the same as the position of an upper surface 350T of the light-shielding member 350 in the Z-axis direction.

The second portion 464 covers the first portion 462, the light adjustment member 240, and the light-shielding member 350. The wavelength conversion member 70 and the optical member 80 are arranged on the first light-transmissive member 460.

A light-transmissive resin, for example, an epoxy resin, a silicone resin, or a resin in which these resins are mixed, glass, or the like can be used for the first light-transmissive member 460, and the same material as the material of the first light-transmissive member 60 of the light-emitting module 100 of the first embodiment can be used. The boundary between the first portion 462 and the second portion 464 is not observed in some cases.

The light-emitting module 400 of the present embodiment operates in a manner similar to those of the other embodiments described above. That is, a part of light emitted from the light-emitting element 30 is emitted through the light adjustment member 240, and the other part thereof is emitted from the periphery of the light adjustment member 240. By adjusting the intensity balance between the luminance of the light emitted through the light adjustment member 240 and the luminance of the light emitted from the periphery of the light adjustment member 240, the luminance unevenness of light above the light-emitting element 30 can be reduced. The light-shielding member 350 is provided to adjust interference of light from another light-emitting element 30 provided across the light-shielding member 350. In the present embodiment, the luminance balance is adjusted in consideration of mixing of light from another light-emitting element 30 via the first portion 462.

Effects of the light-emitting module 400 according to the present embodiment are described.

The light-emitting module 400 according to the present embodiment has effects similar to those of the first embodiment described above. In addition, the following effects are achieved.

In the light-emitting module 400 according to the present embodiment, the first light-transmissive member 460 includes the first portion 462 and the second portion 464. The first portion 462 covers the first surface 12a, the first wiring layer 22, and the light-emitting elements 30. Therefore, the separation distance between the light adjustment member 240 and the light-emitting element 30 can be controlled by the thickness of the first portion 462. The separation distance between the light-shielding member 350 and the first surface 12a can also be controlled by the thickness of the first portion 462. Accordingly, luminance unevenness of light above the light-emitting element 30 is reduced, and at the same time, luminance can be controlled by interference of light from another light-emitting element 30 provided across the light-shielding member 350, so that luminance unevenness of the entire light-emitting module 400 can be reduced.

According to the embodiments described above, light-emitting modules with less luminance unevenness can be achieved.

While several embodiments of the present invention have been described above, these embodiments have been presented by way of example and are not intended to limit the scope of the invention. These novel embodiments may be implemented in various other forms and various omissions, substitutions, and changes may be made without departing from the spirit of the invention. These embodiments and variations thereof are included in the scope and spirit of the invention and are within the scope of the invention described in the claims and equivalents thereof. The aforementioned embodiments can be implemented in combination with each other.

1. A light-emitting module comprising:
a substrate comprising a support member having a first surface and a wiring layer provided on the first surface;
a plurality of light-emitting elements provided on the first surface and electrically connected to the wiring layer;
a plurality of light adjustment members provided on a side of upper surfaces of the plurality of light-emitting elements, the plurality of light adjustment members being spaced apart from the plurality of light-emitting elements, respectively;
at least one light-shielding member provided on the first surface, the at least one light-shielding member being provided surrounding a first light-emitting element among the plurality of light-emitting elements and a first light adjustment member among the plurality of light adjustment members in plan view, and the at least one light-shielding member being provided between the first light-emitting element and a second light-emitting element among the plurality of light-emitting elements in cross-sectional view; and
a light-transmissive member covering the first surface, the wiring layer, the plurality of light-emitting elements, the plurality of light adjustment members, and the at least one light-shielding member.

2. The light-emitting module according to claim 1, wherein a first thickness of the light-shielding member in cross-sectional view is equal to or greater than a second thickness of each of the plurality of light adjustment members in cross-sectional view.

3. The light-emitting module according to claim 1, wherein the plurality of light adjustment members comprise a same material as a material of the light-shielding member.

4. The light-emitting module according to claim 1, wherein, in plan view, an outer periphery of the first light adjustment member has a shape selected from a polygonal shape, a circular shape, and an elliptical shape.

5. The light-emitting module according to claim 1, wherein, in plan view, a region surrounded by an outer periphery of the first light adjustment member overlaps at least a part of a region surrounded by an outer periphery of the first light-emitting element.

6. The light-emitting module according to claim 1, wherein, in cross-sectional view, a position of a lower end of the first light adjustment member coincides with a position of an upper end of the light-shielding member.

7. The light-emitting module according to claim 1, wherein, in cross-sectional view, a lower end of the first light adjustment member is located above a position of an upper end of the light-shielding member.

8. The light-emitting module according to claim 1, wherein, in cross-sectional view, a lower end of the first light adjustment member is located below a position of an upper end of the light-shielding member.

9. The light-emitting module according to claim 1, wherein, in cross-sectional view, the light-shielding member has an inner wall surface at an angle of approximately 90° from the first surface.

10. The light-emitting module according to claim 1, wherein, in cross-sectional view, a length of the light-shielding member between the first light-emitting element and the second light-emitting element is uniform over a thickness direction of the light-shielding member in cross-sectional view.

11. The light-emitting module according to claim 1, wherein the second light-emitting element is adjacent to the first light-emitting element.

12. The light-emitting module according to claim 1, wherein
the plurality of light-emitting elements comprise a third light-emitting element provided between the first light-emitting element and the second light-emitting element, and
in cross-sectional view, the light-shielding member is provided between the third light-emitting element and the second light-emitting element.

13. The light-emitting module according to claim 1, wherein, in plan view, an inner periphery of the light-shielding member has a shape selected from a polygonal shape, a circular shape, and an elliptical shape.

14. The light-emitting module according to claim 1, wherein, in plan view, an inner periphery of the light-shielding member has a shape selected from a quadrangular shape, a shape obtained by chamfering a corner of the quadrangular shape, and a shape obtained by incorporating another figure shape into a corner of the quadrangular shape.

15. The light-emitting module according to claim 1, wherein
in plan view, the light-shielding member comprises a plurality of first light-shielding members spaced apart from each other, and
in plan view, the plurality of first light-shielding members surround the first light-emitting element and surround the first light adjustment member.

16. The light-emitting module according to claim 1, wherein, in plan view, a position of a center of gravity of a region surrounded by an outer periphery of the first light adjustment member coincides with a position of a center of gravity of a region surrounded by an inner periphery of the light-shielding member.

17. The light-emitting module according to claim 1, wherein
in plan view, the light-shielding member surrounds the first light adjustment member, and
a position of a center of gravity of a region surrounded by an outer periphery of the first light adjustment member is different from a position of a center of gravity of a region surrounded by an inner periphery of the light-shielding member.

18. The light-emitting module according to claim 1, wherein
the light-transmissive member comprises a first light-transmissive member and a plurality of second light-transmissive members,
a corresponding second light-transmissive member of the plurality of second light-transmissive members is provided between a corresponding light adjustment member of the plurality of light adjustment members and a corresponding light-emitting element of the plurality of light-emitting elements in cross-sectional view, and
the first light-transmissive member covers the plurality of second light-transmissive members.

19. The light-emitting module according to claim 18, wherein, in plan view, an outer periphery of a corresponding second light-transmissive member of the plurality of second light-transmissive members is located on an outer side of an outer periphery of a corresponding light adjustment member of the plurality of light adjustment members, and is located on an outer side of an outer periphery of a corresponding light-emitting element of the plurality of light-emitting elements.
